(19) United States
(12) Patent Application Publication
(10) Pub. No.: US 2012/0161146 A1
(43) Pub. Date: Jun. 28, 2012

(54) SEMICONDUCTOR DEVICE AND MANUFACTURING METHOD THEREOF

(75) Inventor: Jeoungchill Shim, Kanagawa-ken (JP)

(73) Assignee: Kabushiki Kaisha Toshiba, Tokyo (JP)

(21) Appl. No.: 13/192,780

(22) Filed: Jul. 28, 2011

(30) Foreign Application Priority Data
Dec. 22, 2010 (JP) 2010-285681

(51) Int. Cl. H01L 29/78; H01L 21/336; H01L 29/20

(52) U.S. Cl. 257/76; 257/329; 438/285; 257/E29.262; 257/E29.089; 257/E21.41

(57) ABSTRACT

The present invention includes a semiconductor substrate, a gate electrode which is provided on the semiconductor substrate, a source electrode and a drain elect rode which are provided on the semiconductor substrate to sandwich the gate electrode, and a recess provided below edges of the gate electrode at least on a drain electrode side.

### CROSS-REFERENCE TO RELATED APPLICATION

This application is based upon and claims the benefit of priority from the prior Japanese Patent Application No. 2010-285681 filed on Dec. 22, 2010, the entire contents of which are incorporated herein by reference.

### BACKGROUND

Embodiments described herein related generally to a semiconductor device and a manufacturing method thereof.

With RF FET devices such as a High Electron Mobility Transistor (HEMT) and a Metal Semiconductor Field Effect Transistor (MESFET) which operate at a high voltage, a voltage distribution (electric field) around a gate substantially influences breakdown voltage and current collapse. Particularly, the shape of an edge of a gate on a drain side is closely related thereto.

For example, a gate formed on a substrate by a liftoff process utilizing double layer resist used for GaN or GaAs devices has a taper, and is generally referred to as “trapezoidal gate”. With the gate formed in this way, gate edges have sharp angles with respect to the plane of the substrate, and the electric field concentrates. If the gate metal leaks around the barrier metal and makes direct contact with GaN or GaAs, it causes gate sinking, thereby device performance is degraded.

By contrast with this, the gate formed in an opening formed after a SiN film deposition on a substrate is referred to “T-gate” from its shape. With the gate formed in this way, the gate edges have blunt angles (reverse taper) with respect to the plane of the substrate, and concentration of the electric field is suppressed then so called “trapezoidal gate”.

By suppressing concentration of the electric field which depends on the shape of the gate edges in this way, it is possible to reduce ejection of electrons and gate sinking, and to provide reliable RF devices with higher breakdown voltage.

### BRIEF DESCRIPTION OF THE DRAWINGS

FIG. 1 is a sectional view of a semiconductor element according to an embodiment;

FIG. 2 is a flowchart of a manufacturing process of a semiconductor element according to an embodiment;

FIG. 3A is a sectional view illustrating a manufacturing process of a semiconductor element according to an embodiment;

FIG. 3B is a sectional view illustrating a manufacturing process of a semiconductor element according to an embodiment;

FIG. 3C is a sectional view illustrating a manufacturing process of a semiconductor element according to an embodiment;

FIG. 4 is a sectional view of a semiconductor element according to an embodiment;

FIG. 5 is a flowchart of a manufacturing process of a semiconductor element according to an embodiment;

FIG. 6A is a sectional view illustrating a manufacturing process of a semiconductor element according to an embodiment;

FIG. 6B is a sectional view illustrating a manufacturing process of a semiconductor element according to an embodiment;

FIG. 6C is a sectional view illustrating a manufacturing process of a semiconductor element according to an embodiment;

FIG. 6D is a sectional view illustrating a manufacturing process of a semiconductor element according to an embodiment;

FIG. 6E is a sectional view illustrating a manufacturing process of a semiconductor element according to an embodiment;

FIG. 7 is a sectional view of a semiconductor element according to an embodiment;

FIG. 8 is a sectional view of a semiconductor element according to an embodiment;

FIG. 9 is a sectional view of a semiconductor element according to an embodiment; and

FIG. 10 is a sectional view of a semiconductor element according to an embodiment.

### DETAILED DESCRIPTION

Reference will now be made in detail to the present embodiment of the invention, an example of which is illustrated in the accompanying drawings. Wherever possible, the same reference numbers will be used throughout the drawing to refer to the same or like parts.

Hereinafter, embodiments will be described with reference to the drawings.

### First Embodiment

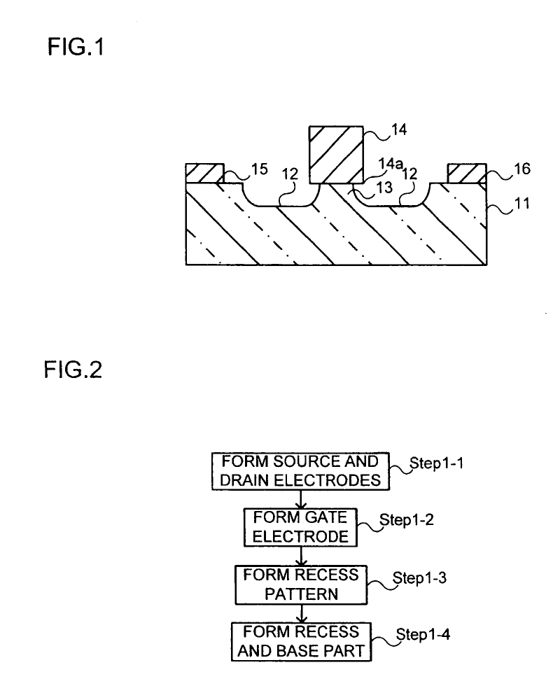

FIG. 1 is a sectional view of a semiconductor element according to the present embodiment. As illustrated in FIG. 1, a recess 12 is provided on a surface of a semiconductor substrate 11 such as a GaAs substrate, and a convex base part 13 is provided in the recess 12. A gate electrode 14 is provided on the base part 13, and the width of the gate electrode 14 is wider than the width of the base part 13 such that edges 14a of the gate electrode 14 are spaced apart from the semiconductor substrate 11. A source electrode 15 and a drain electrode 16 are provided to sandwich the recess 12.

The semiconductor element adopting this structure is formed as follows.

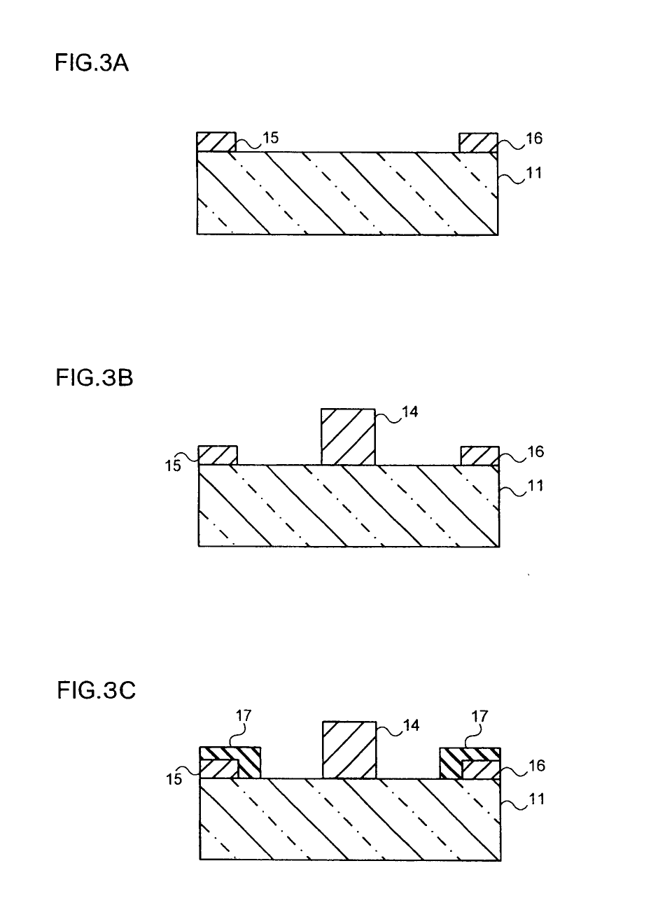

FIG. 2 illustrates a flowchart. As illustrated in FIG. 3A, the source electrode 15 and the drain electrode 16 are formed on the semiconductor substrate 11 by, for example, a lift-off process (Step 1-1).

As illustrated in FIG. 3B, a gate pattern is formed using photoresists, gate metal is accumulated and the photoresists are lifted off to form the gate electrode 14 (Step 1-2).

As illustrated in FIG. 3C, a recess pattern is formed using photoresists 17 above an area including the source electrode 15 and the drain electrode 16 (Step 1-3).

By etching the semiconductor substrate 11 using the photoresists 17 as masks and forming the recess 12, the base part 13 is formed below the gate electrode 14. Then, the photoresists 17 are removed (Step 1-4). In this case, by performing isotropic etching, part (edges) of a lower surface of the gate electrode 14 is exposed and the gate electrode edge is separated from the base part 13.

In this way, the semiconductor element adopting the structure illustrated in FIG. 1 is formed. Metal such as Ag, Ti or W which is frequently used for gate metal is not etched by NH₄F or else which is frequ+enty used as an etching solution upon formation of a recess, so that it is possible to etch the semiconductor substrate with little change of the shape of the gate.

With the semiconductor element formed in this way, the edge 14a of the gate electrode 14 on the drain electrode 16 side is not in contact with the semiconductor substrate 11, so that it is possible to prevent concentration of the electric field on the semiconductor surface. Consequently, by controlling the width of the base part 13 which forms a gate length (Lg) which is more easily controlled than a taper angle in the T-gate structure, it is possible to prevent hot electron ejections and occurrence of gate sinking, and provide highly reliable semiconductor elements with higher break down voltage.

Further, the width of the base part 13 forms the gate length (Lg), so that it is possible to make Lg narrower than the width of the gate electrode, and provide a semiconductor element with better high frequency characteristics.

### Second Embodiment

The semiconductor element according to the present embodiment adopts the same structure as in the first embodiment, and differs from the first embodiment in having two steps in a recess.

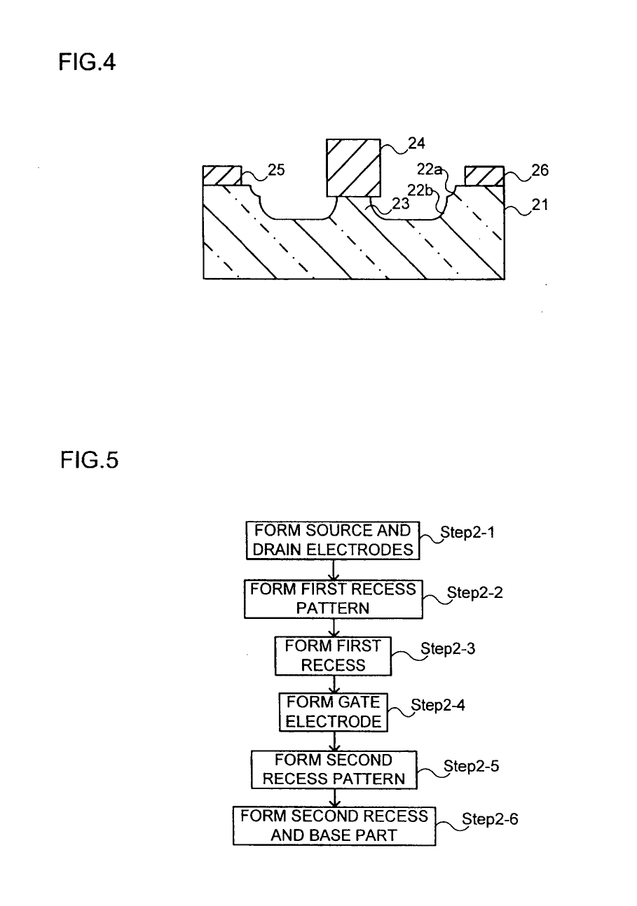

As illustrated in FIG. 4, two steps of recesses 22a and 22b are provided in a semiconductor substrate 21 such as a GaAs substrate, and a convex base part 23 is provided in the recess 22b. A gate electrode 24 is provided on the base part 23, and the width of the gate electrode 24 is wider than the width of the base part 23 such that edges 24a of the gate electrode 24 are spaced apart from the semiconductor substrate 21. A source electrode 25 and a drain electrode 26 are provided to sandwich the recess 22a.

The semiconductor element adopting this structure is formed as follows.

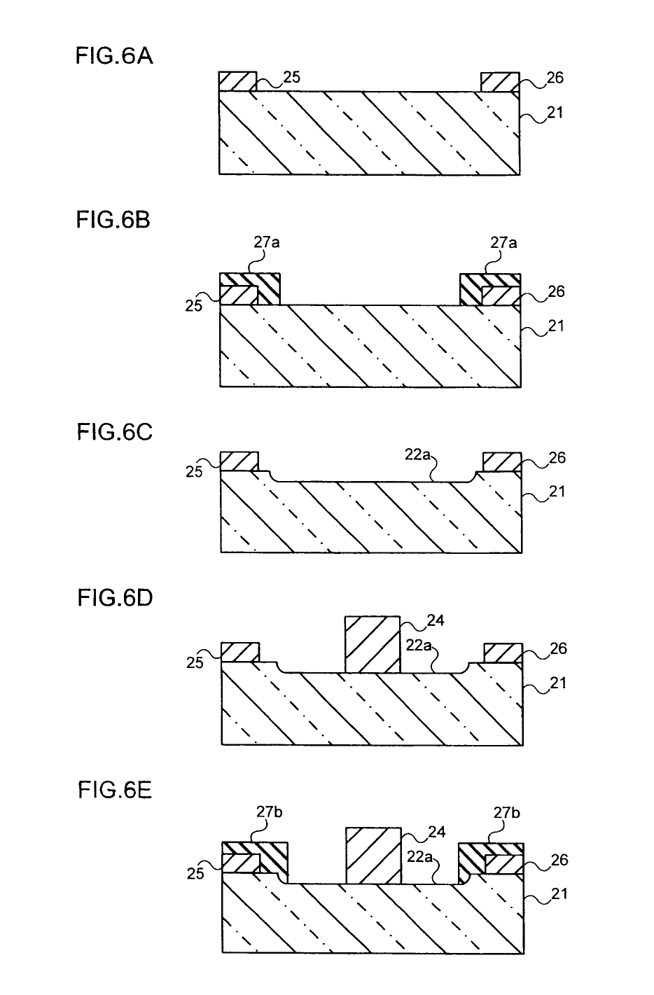

FIG. 5 illustrates a flowchart. As illustrated in FIG. 6A, the source electrode 25 and the drain electrode 26 are formed on the semiconductor element 21 by, for example, a lift-off process (Step 2-1).

As illustrated in FIG. 6B, a first recess pattern is formed using photoresists 27a above an area including the source electrode 25 and the drain electrode 26 (Step 2-2).

As illustrated in FIG. 6C, by etching the semiconductor substrate 21 using the photoresists 27a as masks, the first recess 22a is formed, and the photoresists 27 are removed (Step 2-3).

As illustrated in FIG. 6D, a gate pattern is formed using photoresists, gate metal is accumulated and the photoresists are lifted off to form the gate electrode 24 (Step 2-4).

As illustrated in FIG. 6E, a second recess pattern is formed using photoresists 27b above an area including the source electrode 25 and the drain electrode 26 (Step 2-5).

By etching the semiconductor substrate 21 using the photoresists 27b as masks and forming the recess 22b, the base part 23 is formed below the gate electrode 24. Then, the photoresists 27b are removed (Step 2-6) . In this case, by performing isotropic etching, part of a lower surface (edges) of the gate electrode 24 is exposed and the edge of gate electrode hangs over the base part 23. In this way, the semiconductor element adopting the structure illustrated in FIG. 4 is formed.

The semiconductor element formed in this way can provide the same effect as in the first embodiment. Further, the recess is formed to have two steps, so that it is possible to accurately control the etched depth, and improve stability of characteristics.

Although a GaAs substrate is used as a semiconductor substrate with these embodiments, a compound semiconductor substrate such as a GaN substrate or InN substrate can be used.

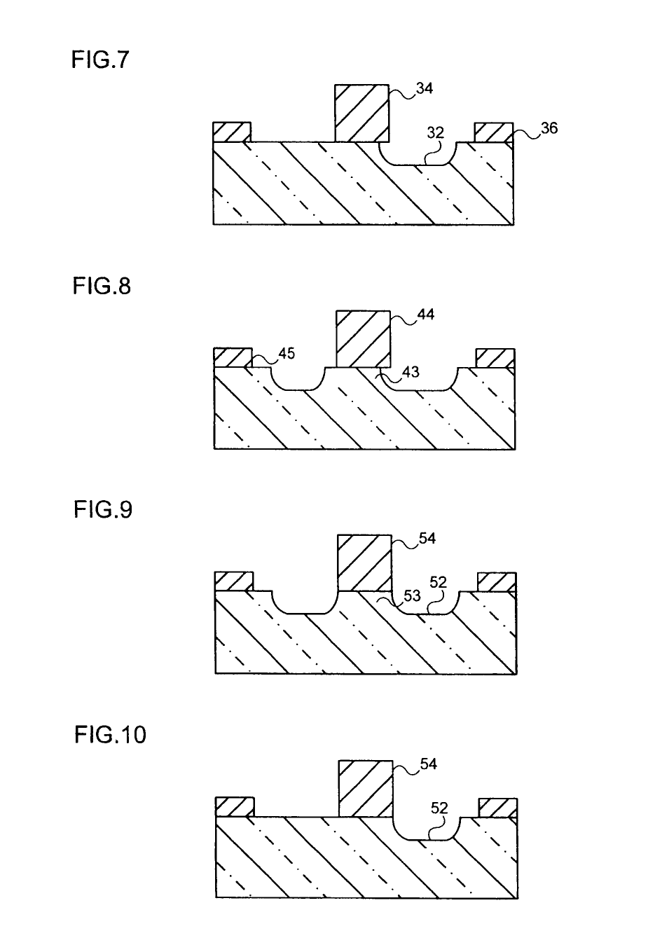

Further, the semiconductor device is by no means limited to the structures described in these embodiments, a recess only needs to be formed at least on the drain electrode side. For example, as illustrated in FIG. 7, a structure is possible where a recess 32 is formed only on a drain electrode 36 side below a gate electrode 34, or, as illustrated in FIG. 8, a structure is possible where an edge of a gate electrode 44 on a source electrode 45 side is on a base part 43.

Further, as illustrated in FIGS. 9 and 10, an edge of a gate electrode 54 on a drain side may not necessarily hang over the semiconductor surface, and, by forming a recess by, for example, anisotropic etching, lateral surfaces of a base part 53 (recess 52 wall surfaces) and the gate electrode 54 may be formed on the same plane surfaces.

While certain embodiments have been described, these embodiments have been presented by way of example only, and are not intended to limit the scope of the inventions. Indeed, the novel embodiments described herein may be embodied in a variety of other forms; furthermore, various omission, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate;
a gate electrode which is provided on the semiconductor substrate;
a source electrode and a drain electrode which are provided on the semiconductor substrate to sandwich the gate electrode; and
a recess which is provided below edges of the gate electrode at least on a side of the drain electrode.

2. The semiconductor device according to claim 1, wherein the gate electrode suspends above the recess at least on the side of the drain electrode.

3. The semiconductor device according to claim 2, wherein the gate electrode suspends toward the recess on the side of the drain electrode and a side of the source electrode.

4. The semiconductor device according to claim 1, wherein the recess is formed to have two steps.

5. The semiconductor device according to claim 1, wherein the semiconductor substrate is a compound semiconductor substrate.

6. The semiconductor device according to claim 5, wherein the compound semiconductor substrate is one of a GaAs substrate, a GaN substrate and an InN substrate.

7. A semiconductor device comprising:
a semiconductor substrate which includes a convex base part;
a gate electrode which is provided on the base part such that at least one of edges suspends;
a drain electrode which is formed on the semiconductor substrate on a side of the edge of the gate electrode which suspends from the surface of base part; and
a source electrode which is formed on an opposite side of the drain electrode across the gate electrode.

8. The semiconductor device according to claim 7, wherein an other edge of the gate electrode projects from the surface of base part.

9. The semiconductor device according to claim 7, wherein a recess including a wall surface of the base part is formed on the semiconductor substrate.

10. The semiconductor device according to claim 7, wherein the recess is formed to have two steps.

11. The semiconductor device according to claim 7, wherein a width of the base part is narrower than a width of the gate electrode.

12. The semiconductor device according to claim 7, wherein the semiconductor substrate is a compound semiconductor substrate.

13. The semiconductor device according to claim 12, wherein the compound semiconductor substrate is one of a GaAs substrate, a GaN substrate and an InN substrate.

14. A method for manufacturing a semiconductor device comprising:
forming a source electrode and a drain electrode on a semiconductor substrate;
forming a gate electrode on the semiconductor substrate between the source electrode and the drain electrode; and
forming a first recess below an edge of the gate electrode by etching using the gate electrode as a mask.

15. The method for manufacturing a semiconductor device according to claim 14, further comprising forming the first recess such that an edge of the gate electrode at least on a side of the drain electrode projects above the first recess.

16. The method for manufacturing a semiconductor device according to claim 15, further comprising forming the first recess such that an edge of the gate electrode on a side of the source electrode projects above the first recess.

17. The method for manufacturing a semiconductor device according to claim 14, wherein the etching is isotropic etching.

18. The method for manufacturing a semiconductor substrate according to claim 14, further comprising forming a second recess on the semiconductor substrate between the source electrode and the drain electrode before the gate electrode is formed.

19. The semiconductor device according to claim 14, wherein the semiconductor substrate is a compound semiconductor substrate.

20. The semiconductor device according to claim 19, wherein the compound semiconductor substrate is one of a GaAs substrate, a GaN substrate and an InN substrate.
